(19) United States
(12) Patent Application Publication
(10) Pub. No.: US 2025/0192013 A1
(43) Pub. Date: Jun. 12, 2025

(54) WIRING SUBSTRATE AND SEMICONDUCTOR PACKAGE INCLUDING A SUBSTRATE WIRING PATTERN

(71) Applicant: SAMSUNG ELECTRONICS CO., LTD., SUWON-SI (KR)

(72) Inventors: Wooseok PARK, Suwon-si (KR); YOUNGCHAN KO, Suwon-si (KR); BYUNG HO KIM, Suwon-si (KR); YONGKOON LEE, Suwon-si (KR); MyungDo CHO, Suwon-si (KR); Jaeyoung CHOI, Suwon-si (KR); Hyeokjin CHU, Suwon-si (KR)

(21) Appl. No.: 18/907,631

(22) Filed: Oct. 7, 2024

(30) Foreign Application Priority Data
Dec. 12, 2023 (KR) 10-2023-0179862

(51) Int. Cl. H01L 23/498; H01L 23/528

(52) U.S. Cl. CPC H01L 23/49816; H01L 23/5283

(57) ABSTRACT

A wiring substrate and semiconductor package including a protection layer, an under-bump pad including an upper part disposed on a top surface of the protection layer and a lower part penetrating the protection layer, a dielectric pattern disposed on the protection layer, and a conductive pattern disposed on the dielectric pattern. The lower part of the under-bump pad is exposed on a bottom surface of the protection layer, and the under-bump pad includes a recess region directed into a bottom surface of the under-bump pad from a top surface of the under-bump pad. The dielectric pattern covers a portion of the under-bump pad and fills the recess region. The conductive pattern includes a pad part disposed on a top surface of the dielectric pattern and a via part that vertically penetrates the dielectric pattern and is coupled to the top surface of the under-bump pad.

### CROSS-REFERENCE TO RELATED APPLICATION

This U.S. non-provisional patent application claims priority under 35 U.S.C. § 119 to Korean Patent Application No. 10-2023-0179862, filed on Dec. 12, 2023, in the Korean Intellectual Property Office, the disclosure of which is incorporated by reference herein in its entirety.

### BACKGROUND

The present inventive concepts relate to a wiring substrate and a semiconductor package including the same, and more particularly to a wiring substrate and a semiconductor package including a substrate wiring pattern.

With the development in electronic industry, the demand for electronic products having high performance, high speed, and compact size have increased. In response to the increasing demand, a packaging technology has emerged, in which a plurality of semiconductor chips are mounted in a single package.

A semiconductor package including an integrated circuit (IC) chip is implemented in electronic products. For example, in the semiconductor package, a semiconductor chip is mounted on a printed circuit board (PCB). In some cases, the semiconductor chip and the PCB are electrically connected by bonding wires or bumps. With the recent development in electronic industry, the semiconductor package is developed and made with a compact size, small weight, and/or low manufacturing cost. In addition, many kinds of semiconductor packages are expanded to accommodate various application fields such as high-capacity mass storage devices.

### SUMMARY

A wiring substrate including a protection layer, an under-bump pad including an upper part disposed on a top surface of the protection layer and a lower part penetrating the protection layer, a dielectric pattern disposed on the protection layer, and a conductive pattern disposed on the dielectric pattern. In one aspect, the lower part of the under-bump pad is exposed on a bottom surface of the protection layer, and the under-bump pad includes a recess region directed into a bottom surface of the under-bump pad from a top surface of the under-bump pad. In one aspect, the dielectric pattern covers a portion of the under-bump pad and fills the recess region. In one aspect, the conductive pattern includes a pad part disposed on a top surface of the dielectric pattern and a via part that vertically penetrates the dielectric pattern and is coupled to the top surface of the under-bump pad. In one aspect, a width of the upper part of the under-bump pad is greater than a width of the pad part of the conductive pattern, and the via part of the conductive pattern is spaced apart from the recess region.

A semiconductor package including a package substrate, a first apparatus disposed on the package substrate, and a second apparatus disposed on the package substrate and horizontally spaced apart from the first apparatus. In one aspect, the package substrate includes a lower redistribution layer, a bridge chip disposed on the lower redistribution layer, an upper redistribution layer disposed on the bridge chip, and a vertical connection terminal disposed between and connected to the lower redistribution layer and the upper redistribution layer. In one aspect, the lower redistribution layer includes a protection layer, an under-bump pad disposed on a top surface of the protection layer and penetrating the protection layer, where the under-bump pad is exposed on a bottom surface of the protection layer, a dielectric pattern disposed on the protection layer and covering the under-bump pad, and a conductive pattern disposed on the dielectric pattern. In one aspect, the conductive pattern includes a pad part disposed on a top surface of the dielectric pattern and a via part that vertically penetrates the dielectric pattern and is coupled to the under-bump pad. In one aspect, the bridge chip and the vertical connection terminal are connected to a top surface of the pad part of the conductive pattern, and the via part of the conductive pattern has an annular shape, a ring shape, or a closed curve shape in a plan view.

A wiring substrate including a protection layer, an under-bump pad disposed on a top surface of the protection layer, where the under-bump pad includes a recess region directed into a bottom surface of the under-bump pad from a top surface of the under-bump pad, a dielectric pattern disposed on the protection layer, where the dielectric pattern covers a portion the under-bump pad and fills the recess region, and a conductive pattern disposed on the dielectric pattern. In one aspect, the conductive pattern includes a pad part disposed on a top surface of the dielectric pattern, and a via part that vertically penetrates the dielectric pattern and is coupled to the top surface of the under-bump pad. In one aspect, the via part of the conductive pattern surrounds the recess region in a plan view, a first width of a bottom end of the via part of the conductive pattern is less than a second width of a top end of the via part of the conductive pattern, and the first width is about 0.9 times to about 1 time the second width.

### BRIEF DESCRIPTION OF DRAWINGS

FIG. 1 illustrates a cross-sectional view of a wiring substrate according to some embodiments of the present inventive concepts.

FIG. 2 illustrates an enlarged view of section A in FIG. 1.

FIG. 3 illustrates an exploded perspective view of an under-bump pad and a conductive pattern in FIG. 2.

FIGS. 4, 5, 6, and 7 illustrate plan views of an under-bump pad and a conductive pattern.

FIG. 8 illustrates a cross-sectional view of a semiconductor package according to some embodiments of the present inventive concepts.

FIG. 9 illustrates a cross-sectional view of a wiring substrate according to some embodiments of the present inventive concepts.

FIG. 10 illustrates a cross-sectional view of a semiconductor package according to some embodiments of the present inventive concepts.

FIGS. 11, 12, 13, 14, and 15 illustrate a method for forming a wiring substrate according to some embodiments of the present inventive concepts.

### DETAILED DESCRIPTION

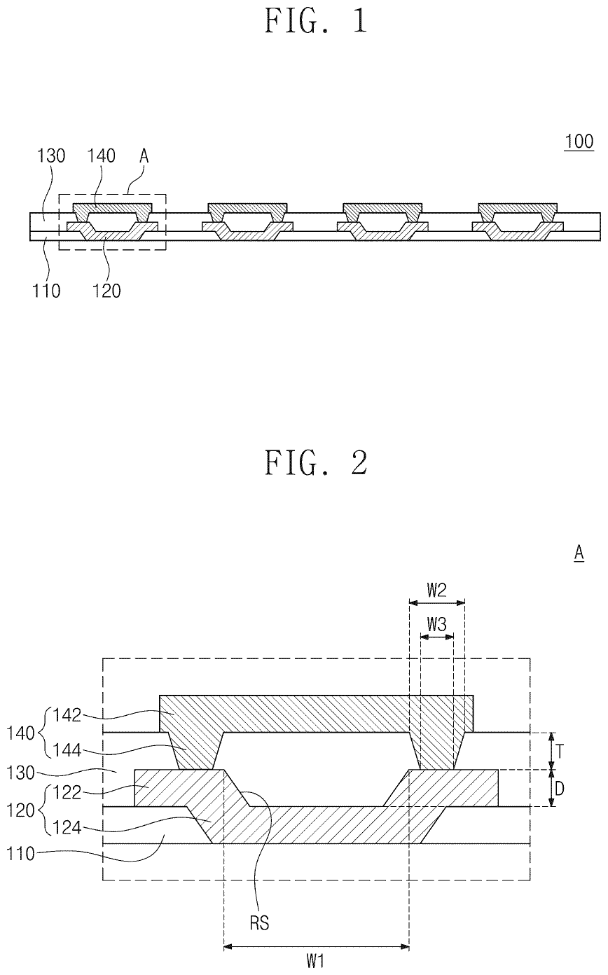

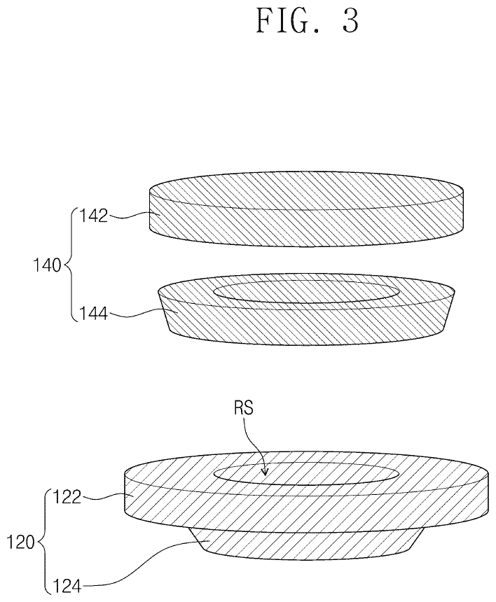

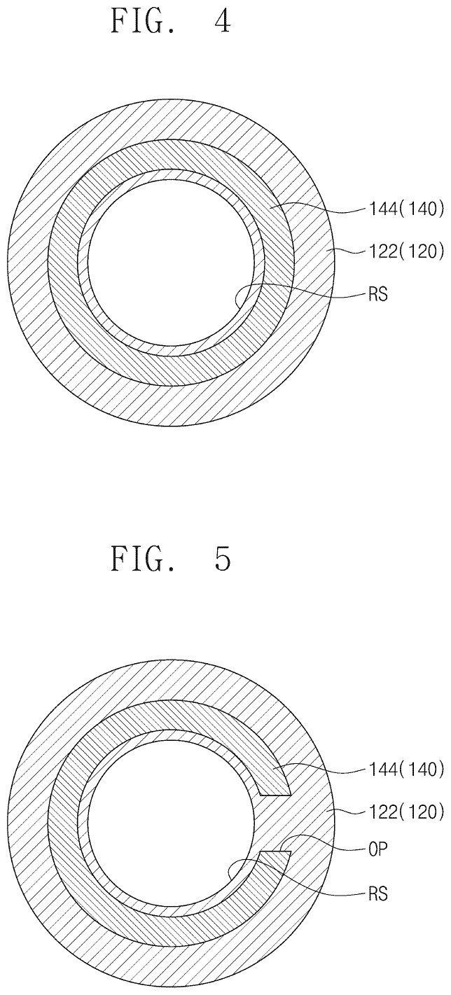

The following detailed description describes a wiring substrate according to some embodiments of the present inventive concepts. FIG. 1 illustrates a cross-sectional view of a wiring substrate according to some embodiments of the present inventive concepts. FIG. 2 illustrates an enlarged view of section A in FIG. 1. FIG. 3 illustrates an exploded perspective view of an under-bump pad and a conductive pattern in FIG. 2. FIGS. 4, 5, 6, and 7 illustrate plan views of an under-bump pad and a conductive pattern.

Referring to FIGS. 1 and 2, a wiring substrate 100 may be provided. The wiring substrate 100 may be a redistribution substrate. In some cases, a redistribution substrate includes one or more redistribution layers. For example, the redistribution layer enables the routing of signals from a bounding pad of a semiconductor chip to external connectors. In some cases, for example, the wiring substrate 100 may include one or more substrate wiring layers. The substrate wiring layer may include a substrate dielectric pattern 130 and substrate wiring patterns 140 disposed in the substrate dielectric pattern 130. In some embodiments, the wiring substrate 100 may further include a substrate protection layer 110 and under-bump pads 120. The substrate protection layer 110 and the under-bump pads 120 may be coupled to an external wiring layer and coupled to external terminals, such as solder balls, for mounting the wiring substrate 100 on an external substrate or a motherboard. The embodiment of FIG. 1 depicts one substrate wiring layer is provided on the external wiring layer, and the substrate wiring patterns 140 of the substrate wiring layer may be coupled to a pad layer for mounting a semiconductor chip, a semiconductor device, or a semiconductor apparatus on the wiring substrate 100.

The substrate protection layer 110 may cover a bottom surface of the substrate wiring layer. In some cases, the substrate protection layer 110 may be disposed on a bottom surface of the substrate wiring layer. The substrate protection layer 110 may include a dielectric polymer or a photo-imageable dielectric (PID). For example, the photo-imageable dielectric may include one or more of photosensitive polyimide, polybenzoxazole (PBO), phenolic polymers, and benzocyclobutene polymers. In some embodiments, the substrate protection layer 110 may include a dielectric polymer or a dielectric material. For example, the substrate protection layer 110 may include silicon oxide (SiO), silicon nitride (SiN), or silicon oxynitride (SiON).

The under-bump pads 120 may be disposed on the substrate protection layer 110. In some cases, a bottom surface of the under-bump pads 120 may be coplanar with a bottom surface of the substrate protection layer 110. The under-bump pads 120 may horizontally extend on the substrate protection layer 110. The under-bump pads 120 may be disposed on a top surface of the substrate protection layer 110. The under-bump pads 120 may protrude away from the top surface of the substrate protection layer 110. The under-bump pads 120 may include a conductive material. For example, the under-bump pads 120 may include metal, such as copper (Cu).

The under-bump pads 120 may correspond to substrate external pads. In some cases, for example, the substrate external pads are coupled to external terminals. For example, the under-bump pads 120 may include an upper part 122 and a lower part 124.

The upper parts 122 of the under-bump pads 120 may be disposed on the top surface of the substrate protection layer 110. In some cases, for example, a bottom surface of the upper parts 122 of the under-bump pads 120 may be disposed on the top surface of the substrate protection layer 110. The upper parts 122 of the under-bump pads 120 may horizontally extend on the top surface of the substrate protection layer 110. The upper parts 122 of the under-bump pads 120 may have a circular shape in a plan view. In some embodiments, the upper parts 122 of the under-bump pads 120 may have a tetragonal shape, a polygonal shape, a linear shape, a ring shape, or any other suitable shapes in a plan view. The upper parts 122 of the under-bump pad 120 may be a wiring part or a pad part of the under-bump pads 120. For example, the upper parts 122 of the under-bump pad 120 are coupled to the substrate wiring patterns 140. In some cases, for example, a pad part refers to conductive areas for making electrical connections with another component or element. In some cases, for example, a wiring part may transmit signals or distribute power.

The lower parts 124 of the under-bump pads 120 may vertically penetrate the substrate protection layer 110. The lower parts 124 of the under-bump pads 120 may extend from bottom surfaces of the upper parts 122 of the under-bump pads 120. The lower parts 124 of the under-bump pads 120 may downwardly protrude from the bottom surfaces of the upper parts 122 of the under-bump pads 120. The lower parts 124 of the under-bump pads 120 may be exposed on a bottom surface of the substrate protection layer 110. For example, a bottom surface of the lower parts 124 of the under-bump pads 120 may be coplanar with a bottom surface of the substrate protection layer 110. A width, measured in the horizontal direction, of the lower parts 124 of the under-bump pads 120 may decrease with increasing distance away from the upper parts 122 of the under-bump pads 120. For example, the lower parts 124 of the under-bump pads 120 may have a tapered shape. The lower parts 124 of the under-bump pads 120 may have the outer lateral surfaces inclined to the bottom surfaces of the upper parts 122 of the under-bump pads 120.

However, embodiments of the present inventive concepts are not necessarily limited thereto. According to some embodiments of the present inventive concepts, the lower parts 124 of the under-bump pads 120 may have constant widths and may have outer lateral surfaces perpendicular to the bottom surfaces of the upper parts 122 of the under-bump pads 120. The lower parts 124 of the under-bump pads 120 may have a circular shape in the plan view. In some embodiments, the lower parts 124 of the under-bump pads 120 may have a tetragonal shape, a polygonal shape, a ring shape, or any other suitable shapes in the plan view. The lower parts 124 of the under-bump pads 120 may be exposed on the bottom surface of the substrate protection layer 110. In some cases, the external terminals may be coupled to the lower parts 124 of the under-bump pads 120.

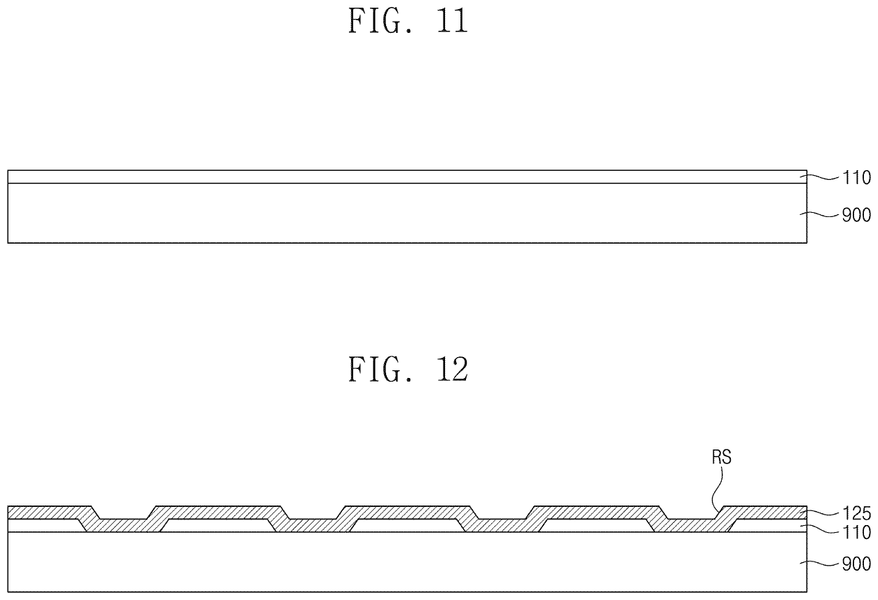

In some cases, the lower parts 124 of the under-bump pads 120 may have large widths. As a result, recesses RS are formed on the upper parts 122 of the under-bump pads 120 when fabricating the wiring substrate 100. Further detail on the method for fabricating a wiring substrate is described with reference to FIGS. 11-15.

According to some embodiments, each of the under-bump pads 120 may include the recess RS. Further detail on the recess RS of an under-bump pad 120 is described below.

Referring to FIGS. 1 to 3, the recess RS may be formed on the upper part 122 of the under-bump pad 120. The recess RS may be directed inwardly into the under-bump pad 120 from the top surface of the upper part 122 of the under-bump pad 120. The recess RS may have a width W1 that decreases with decreasing distance from the top surface of the upper part 122 toward the bottom surface of the upper part 122 of the under-bump pad 120. For example, the recess RS may have a tapered shape. The recess RS may have an inner lateral surface inclined to the top surface of the upper part 122. In some embodiments, when the outer lateral surface of the lower part 124 is perpendicular to the bottom surface of the upper part 122, the inner lateral surface of the recess RS may also be perpendicular to the top surface of the upper part 122. The width W1 of the recess RS may be less than a width of the under-bump pad 120. In some cases, a depth D of the recess RS may be less than a total thickness of the under-bump pad 120. In some cases, the total thickness of the under-bump pad 120 is measured from the top surface of the upper part 122 of the under-bump pad 120 to the bottom surface of the lower part 124 of the under-bump pad 120. The depth D of the recess RS may range from about 3 micrometers to about 5 micrometers. The recess RS may have a same or similar shape, in the plan view, as the shape of the under-bump pad 120. For example, the recess RS may have a circular shape in the plan view. In some cases, the word “about” may be inclusive. For example, the depth D of the recess RS may range from about 3 micrometers to about 5 micrometers may include the lower bound and the upper bound. For example, the depth D of the recess RS may be 3 micrometers or 5 micrometers.

As the recess RS is formed on the under-bump pad 120, the under-bump pad 120 may have a shape that conformally covers a portion of the top surface of the substrate protection layer 110. In some cases, the under-bump pad 120 covers the bottom and inner lateral surfaces of an opening formed in the substrate protection layer 110. For example, the under-bump pad 120 may be a conductive layer having a substantially uniform thickness formed on the top surface of the substrate protection layer 110 and on the bottom and inner lateral surfaces of the opening formed in the substrate protection layer 110. The bottom surface of the opening may be an imaginary surface that is coplanar to the bottom surface of the substrate protection layer 110. In some cases, the under-bump pad 120 is disposed in the opening of the substrate protection layer 110. For example, the lower part 124 of the under-bump pad 120 is in the same level as the substrate protection layer 110. However, the present inventive concepts are not necessarily limited thereto. For example, the conductive layer (e.g., the under-bump pad 120) may have a non-uniform thickness.

In some embodiments, the under-bump pad 120 may further include a seed layer. For example, the seed layer may be interposed between the under-bump pad 120 and the substrate protection layer 110. The seed layer may cover the bottom surface of the under-bump pad 120. The seed layer may include a metallic material such as gold (Au).

According to some embodiments, the wiring substrate 100 and a semiconductor package including the wiring substrate 100 may be provided in the form of a ball grid array (BGA) type, a fine ball-grid array (FBGA) type, or a land grid array (LGA) type.

In some embodiments, the substrate dielectric pattern 130 may be disposed on the substrate protection layer 110. On the top surface of the substrate protection layer 110, the substrate dielectric pattern 130 may cover the under-bump pads 120. For example, the substrate dielectric pattern 130 may cover side surfaces and a portion of an upper surface of the substrate protection layer 110. In some cases, the side surfaces refer to the inner lateral surface and the outer lateral surface. The substrate dielectric pattern 130 may fill the recesses RS of the under-bump pads 120. In some cases, an upper surface of the substrate dielectric pattern 130 may be at a higher level than the upper surface of the under-bump pads 120.

In some cases, the substrate dielectric pattern 130 may include a dielectric polymer or a photo-imageable dielectric (PID). For example, the photo-imageable dielectric may include one or more of photosensitive polyimide, polybenzoxazole (PBO), phenolic polymers, and benzocyclobutene polymers. In some embodiments, the substrate dielectric pattern 130 may include a dielectric material. For example, the substrate dielectric pattern 130 may include silicon oxide (SiO), silicon nitride (SiN), silicon oxynitride (SiON), or a dielectric polymer.

In some embodiments, the substrate wiring patterns 140 may be disposed on the substrate dielectric pattern 130. The substrate wiring patterns 140 may horizontally extend on the substrate dielectric pattern 130. The substrate wiring patterns 140 may be disposed on a top surface of the substrate dielectric pattern 130. The substrate wiring patterns 140 may protrude onto the top surface of the substrate dielectric pattern 130. In some cases, the substrate wiring patterns 140 may be disposed on and in contact with the under-bump pads 120. The substrate wiring patterns 140 may include a conductive material. For example, the substrate wiring patterns 140 may include metal, such as copper (Cu).

In some cases, the substrate wiring patterns 140 may have a damascene structure. For example, the damascene structure is a fabrication method used in semiconductor manufacturing to form conductive patterns by selectively depositing and removing materials on a substrate or substrate layer. For example, the substrate wiring patterns 140 may each have a pad part 142 and a via part 144.

The pad parts 142 of the substrate wiring patterns 140 may be disposed on the top surface of the substrate dielectric pattern 130. The pad parts 142 of the substrate wiring patterns 140 may horizontally extend on the top surface of the substrate dielectric pattern 130. The pad parts 142 of the substrate wiring patterns 140 may have a circular shape in the plan view. In some embodiments, the pad parts 142 of the substrate wiring patterns 140 may have a tetragonal shape, a polygonal shape, a linear shape, or any other suitable shapes in the plan view. A width of the substrate wiring pattern 140 or the pad part 142 of the substrate wiring pattern 140 may be less than the width of the under-bump pad 120 or the upper part 122 of the under-bump pad 120. The pad parts 142 of the substrate wiring patterns 140 may be coupled to pads for mounting a semiconductor chip, a semiconductor device, or a semiconductor apparatus on the wiring substrate 100.

The via parts 144 of the substrate wiring patterns 140 may vertically penetrate the substrate dielectric pattern 130. The via parts 144 of the substrate wiring patterns 140 may extend from bottom surfaces of the pad parts 142 of the substrate wiring patterns 140 toward the upper surface of the upper part 122 of the under-bump pad 120. The via parts 144 of the substrate wiring patterns 140 may downwardly protrude from the bottom surfaces of the pad parts 142 of the substrate wiring patterns 140. The via parts 144 of the substrate wiring patterns 140 may vertically penetrate the substrate dielectric pattern 130 and coupled to the top surfaces of the upper parts 122 of the under-bump pads 120.

Referring to FIGS. 1 to 4, the via part 144 of the substrate wiring pattern 140 may have an annular shape, a ring shape, or a closed curve shape in the plan view. For example, the via part 144 of the substrate wiring pattern 140 may surround the recess RS of the under-bump pad 120. The via part 144 of the substrate wiring pattern 140 may be spaced apart from the recess RS. The via part 144 of the substrate wiring pattern 140 may have a bottom surface whose planar shape is larger than that of the recess RS. For example, the recess RS may be disposed inside the via part 144 of the substrate wiring pattern 140 in the plane view. For example, the via part 144 of the substrate wiring pattern 140 encircles the recess RS. The substrate dielectric pattern 130 may fill a space or a region surrounded by the pad part 142 of the substrate wiring pattern 140, the upper part 122 of the under-bump pad 120, and the recess RS.

In contrast to the embodiment of the via part 144 of the substrate wiring pattern 140 shown in FIG. 4, FIGS. 5-7 illustrate some embodiments of the via part 144 of the substrate wiring pattern 140. For example, the via part 144 of the substrate wiring pattern 140 may include a curve shape having an opening in the plan view.

According to some embodiments, as shown in FIG. 5, the via part 144 of the substrate wiring pattern 140 may include a C shape that extends along an edge of the recess RS in the plan view. For example, similar to the embodiment shown in FIG. 4, the via part 144 of the substrate wiring pattern 140 may have an opening OP formed on one side of the via part 144. In some cases, the inner and outer sides of the via part 144 are connected to each other.

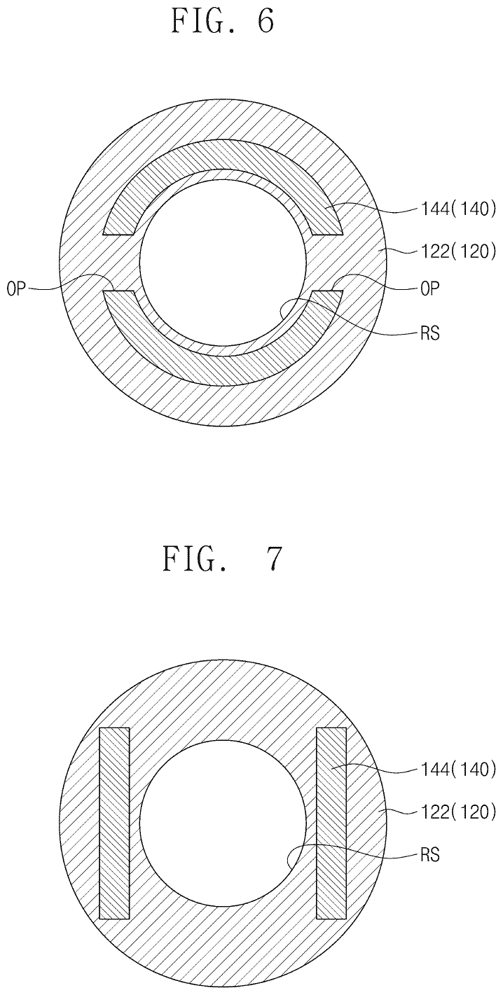

According to some embodiments, as shown in FIG. 6, the substrate wiring pattern 140 may have a plurality of via parts 144 disposed below the pad part 142 of the substrate wiring pattern 140. Each of the via parts 144 may be disposed adjacent to the recess RS. For example, each of the via parts 144 may have a U shape that extends along an edge of the recess RS in the plan view. The via parts 144 may be spaced apart from each other. The via parts 144 may be opposite to each other across the recess RS. For example, similar to the embodiment shown in FIG. 4, the via part 144 of the substrate wiring pattern 140 may have a plurality of openings OP formed on ends of the via part 144. In some cases, the inner and outer sides of the via part 144 are connected to each other. FIG. 6 depicts substrate wiring pattern 140 including two via parts 144, but the present inventive concepts are not necessarily limited thereto. For example, the substrate wiring pattern 140 may have three or more via parts 144.

According to some embodiments, as shown in FIG. 7, the substrate wiring pattern 140 may have a plurality of via parts 144 disposed below the pad part 142 of the substrate wiring pattern 140. Each of the via parts 144 may be disposed adjacent to the recess RS. For example, each of the via parts 144 may have a linear shape that extends along one direction in the plan view. In some cases, each of the via parts 144 may have a stripe shape including linear patterns spaced apart from each other. The via parts 144 may be spaced apart from each other. The via parts 144 may be opposite to each other across the recess RS. FIG. 7 depicts substrate wiring pattern 140 including two via parts 144, but the present inventive concepts are not necessarily limited thereto. The substrate wiring pattern 140 may include three or more via parts 144.

Referring to FIGS. 1 to 4, the via part 144 of the substrate wiring pattern 140 may have widths W2 and W3 that decrease with increasing distance from a lower surface of the pad part 142 of the substrate wiring pattern 140 toward a lower surface of the via part 144 of the substrate wiring pattern 140. For example, the via part 144 of the substrate wiring pattern 140 may have a tapered shape. The via part 144 of the substrate wiring pattern 140 may have an outer lateral surface inclined to the bottom surface of the pad part 142 of the substrate wiring pattern 140. In some cases, an upper surface (or top end) of the via part 144 has a width W2. In some cases, a lower surface (or a bottom end) of the via part 144 has a width W3. In some cases, the width W2 is greater than the width W3. In some embodiments, the width W3 of the bottom end of the via part 144 may be about 0.9 times to 1.0 time the width W2 of the top end of the via part 144. The present inventive concepts, however, are not necessarily limited thereto. For example, the via part 144 of the substrate wiring pattern 140 may have a constant width, and the outer lateral surface of the via part 144 may be perpendicular to the bottom surface of the pad part 142. For example, in the substrate wiring pattern 140, the width W3 of the bottom end of the via part 144 may be the same the width W2 of the top end of the via part 144.

When the width W3 of the bottom end of the via part 144 is less than about 0.9 times the width W2 of the top end of the via part 144 in the substrate wiring pattern 140, a difference in area between the top end and bottom end of the via part 144 may induce an increase in resistance of the via part 144. In some cases, when the bottom end of the via part 144 has a small thickness, the substrate wiring pattern 140 may be vulnerable to external impact. In addition, the top end of the via part 144 may have a small area, and thus an increased contact area may be provided between the via part 144 and the under-bump pad 120. In some cases, the widths W2 and W3 of the via part 144 of the substrate wiring pattern 140 may range from about 5 micrometers to about 15 micrometers. The via part 144 of the substrate wiring pattern 140 may have a height T range from about 5 micrometers to about 20 micrometers. When the height T of the via part 144 of the substrate wiring pattern 140 is greater than about 20 micrometers, the width W3 of the bottom end of the via part 144 and the width W2 of the top end of the via part 144 may be adjusted during the fabrication of the wiring substrate 100. Further detail on the method of fabricating a wiring substrate is described with reference to FIGS. 11-15.

According to some embodiments of the present inventive concepts, the substrate wiring pattern 140 may have a reduced difference between upper and lower portions of the via part 144. For example, the lower portion of the via part 144 might not be excessively small. Therefore, the via part 144 may have a small electrical resistance and a small contact resistance between the via part 144 and the under-bump pad 120. Accordingly, the wiring substrate 100 may improve the electrical properties. In addition, as the lower portion of the via part 144 is not excessively small, the via part 144 may not be damaged by external impact. Accordingly, the wiring substrate 100 may increase in structural stability.

For convenience of description, the via part 144 and the pad part 142 of the substrate wiring pattern 140 are illustrated as two distinct elements in FIG. 3, but the via part 144 and the pad part 142 may be connected into a single unitary piece. For example, the pad part 142 of the substrate wiring pattern 140 disposed on the substrate dielectric pattern 130 may be a head part used as a horizontal line or pad, and the via part 144 of the substrate wiring pattern 140 may be a tail part. In some cases, the substrate wiring pattern 140 may have a pi (x) shape in the cross-sectional view (e.g., as shown in FIG. 2).

In some embodiments, the substrate wiring pattern 140 may further include a seed layer. For example, the seed layer may be interposed between the substrate wiring pattern 140 and the substrate dielectric pattern 130. For example, the seed layer may cover the substrate dielectric pattern 130. In some cases, the substrate wiring pattern 140 may cover the seed layer. The seed layer may extend between the substrate wiring pattern 140 and the under-bump pad 120. The seed layer may include a metallic material, such as gold (Au).

In some cases, same components or similar components are denoted with the same reference numerals, and a repetitive description may be omitted or abridged for the convenience of description. The following description describes the difference between the embodiments of FIGS. 1 to 7 and other embodiments of the present inventive concept.

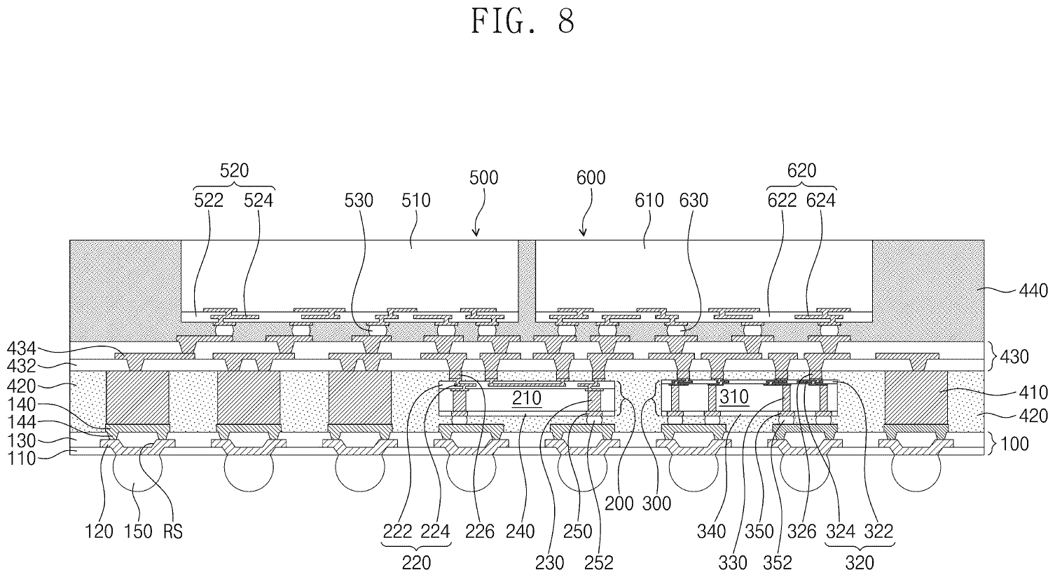

FIG. 8 illustrates a cross-sectional view of a semiconductor package according to some embodiments of the present inventive concepts. Referring to FIG. 8, a lower redistribution layer 100 may be provided. The lower redistribution layer 100 may be referred to as the wiring substrate 100 described with reference to FIGS. 1 and 2.

External terminals 150 may be disposed on bottom surfaces of the under-bump pads 120 exposed on the bottom surface of the substrate protection layer 110. The external terminals 150 may include solder balls or solder bumps. In some cases, a semiconductor package may be a ball grid array (BGA) type semiconductor package, a fine ball-grid array (FBGA) type semiconductor package, or a land grid array (LGA) type semiconductor package based on the type and arrangement of the external terminals 150.

A bridge chip 200 may be disposed on the lower redistribution layer 100. The bridge chip 200 may be disposed on a top surface of the lower redistribution layer 100. In some cases, the bridge chip 200 may include a front surface and a rear surface. In some cases, front surface may include an active surface of an integrated element in a semiconductor chip, a surface on which wiring lines are formed, or a surface on which pads of a semiconductor chip are formed. In some cases, rear surface may include a surface opposite to the front surface. The rear surface of the bridge chip 200 may be directed toward the lower redistribution layer 100. For example, the bridge chip 200 may be disposed in a face-up state on the lower redistribution layer 100. The bridge chip 200 may include a bridge base layer 210 and a bridge wiring layer 220.

The bridge base layer 210 may include a semiconductor substrate. For example, the bridge base layer 210 may be a semiconductor substrate such as a semiconductor wafer. The bridge base layer 210 may be a silicon (Si) substrate, a silicon-on-insulator (SOI) substrate, a germanium (Ge) substrate, a germanium-on-insulator (GOI) substrate, a silicon-germanium (SiGe) substrate, a III-V group semiconductor substrate, or an epitaxial film substrate obtained by performing selective epitaxial growth (SEG). In some cases, for example, the bridge base layer 210 may include silicon (Si), germanium (Ge), silicon germanium (SiGe), gallium arsenic (GaAs), indium gallium arsenic (InGaAs), aluminum gallium arsenic (AlGaAs), or a combination thereof.

The bridge wiring layer 220 may be disposed on a top surface of the bridge base layer 210. For example, the bridge wiring layer 220 may include a bridge dielectric pattern 222 and a bridge wiring pattern 224 formed on the top surface of the bridge base layer 210. In some cases, the bridge wiring layer 220 may further include a circuit pattern or a protection layer.

The bridge dielectric pattern 222 may include a dielectric material. For example, the bridge dielectric pattern 222 may include silicon oxide (SiO), silicon nitride (SiN), silicon oxynitride (SiON), silicon carbonitride (SiCN), or a dielectric polymer. In some embodiments, the bridge dielectric pattern 222 may include a dielectric polymer or a photo-imageable dielectric (PID). For example, the photo-imageable dielectric may include one or more of photosensitive polyimide, polybenzoxazole, phenolic polymers, and benzocyclobutene polymers.

The bridge wiring pattern 224 may be disposed in the bridge dielectric pattern 222. The bridge wiring pattern 224 may be electrically connected to a first semiconductor chip 500 and a second semiconductor chip 600. A portion of the bridge wiring pattern 224 may be exposed on a top surface of the bridge dielectric pattern 222. The bridge wiring pattern 224 exposed on the top surface of the bridge dielectric pattern 222 may be bridge upper pads of the bridge chip 200. In some embodiments, the bridge upper pads of the bridge chip 200 may be separate pads disposed on the top surface of the bridge dielectric pattern 222, and the bridge wiring pattern 224 may be electrically connected to the bridge upper pads. The bridge wiring pattern 224 may include a conductive material. For example, the bridge wiring pattern 224 may include copper (Cu) or aluminum (Al).

FIG. 8 depicts one layer of the bridge dielectric pattern 222, but the present inventive concepts are not necessarily limited thereto. The bridge dielectric pattern 222 may include a plurality of dielectric layers, and the bridge wiring pattern 224 may be a wiring pattern disposed in the plurality of dielectric layers.

Bridge connection terminals 226 may be disposed on the bridge wiring layer 220. The bridge connection terminals 226 may be coupled to top surfaces of the bridge upper pads. In some cases, the bridge connection terminals 226 may be coupled to top surfaces of the bridge wiring pattern 224. The bridge connection terminals 226 may include solder bumps or pad patterns.

The bridge chip 200 may further include bridge vias 230 that vertically penetrate the bridge base layer 210. The bridge vias 230 may penetrate the bridge base layer 210 and connect to the bridge wiring layer 220. The bridge vias 230 may include a metallic material such as copper (Cu) or tungsten (W).

A bridge protection layer 240 may be disposed on a bottom surface of the bridge base layer 210. For example, the bridge protection layer 240 may be disposed between the bridge base layer 210 and the lower redistribution layer 100. The bridge protection layer 240 may include a dielectric polymer or a photo-imageable dielectric (PID). For example, the photo-imageable dielectric may include one or more of photosensitive polyimide, polybenzoxazole, phenolic polymers, and benzocyclobutene polymers.

In some cases, bridge lower pads 250 may be disposed in the bridge base layer 210. The bridge lower pads 250 may be exposed on a bottom surface of the bridge protection layer 240. The bridge vias 230 may be coupled to top surfaces of the bridge lower pads 250. In some cases, the bridge lower pads 250 may be electrically connected to the bridge wiring pattern 224 of the bridge wiring layer 220 through the bridge vias 230.

The bridge chip 200 may be mounted on the lower redistribution layer 100. The bridge chip 200 may be flip-chip mounted on the lower redistribution layer 100. For example, first inner connection terminals 252 may be disposed on the bridge lower pads 250 of the bridge chip 200. In some cases, the first inner connection terminals 252 may be disposed between the bridge lower pads 250 of the bridge chip 200 and the substrate wiring patterns 140 of the lower redistribution layer 100. The first inner connection terminals 252 may connect the bridge lower pads 250 to the substrate wiring patterns 140 of the lower redistribution layer 100. In some cases, for example, the first inner connection terminals 252 may include solder balls.

In some embodiments, an inner chip 300 may be disposed on the lower redistribution layer 100. The inner chip 300 may include a semiconductor chip having an integrated chip, a passive element chip, or a dummy chip. The present inventive concepts, however, are not necessarily limited thereto. For example, the inner chip 300 might not be disposed on the lower redistribution layer 100. In an embodiment, the inner chip 300 includes a passive element chip. The inner chip 300 may include an inner chip base layer 310 and an inner chip wiring layer 320.

The inner chip base layer 310 may include a semiconductor substrate. For example, the inner chip base layer 310 may be a semiconductor substrate such as a semiconductor wafer. A passive element may be disposed on a top surface of the inner chip base layer 310. The passive element may include a resistor, a capacitor, or an inductor. The inner chip 300 may have a top surface as an active surface and a bottom surface as an inactive surface. For example, the inner chip 300 may be disposed in a face-up state on the lower redistribution layer 100.

The inner chip wiring layer 320 may be disposed on the top surface of the inner chip base layer 310. For example, the inner chip wiring layer 320 may include an inner chip dielectric pattern 322 and an inner chip wiring pattern 324 formed on the top surface of the inner chip base layer 310. In some cases, the inner chip wiring layer 320 may further include a circuit pattern or a protection layer.

On the top surface of the inner chip base layer 310, the inner chip dielectric pattern 322 may cover the passive element. The inner chip dielectric pattern 322 may include a dielectric material. For example, the inner chip dielectric pattern 322 may include silicon oxide (SiO), silicon nitride (SiN), silicon oxynitride (SiON), silicon carbonitride (SiCN), or a dielectric polymer.

The inner chip wiring pattern 324 may be disposed in the inner chip dielectric pattern 322. The inner chip wiring pattern 324 may be electrically connected to the passive element formed on the top surface of the inner chip base layer 310. A portion of the inner chip wiring pattern 324 may be exposed on a top surface of the inner chip dielectric pattern 322. The inner chip wiring pattern 324 exposed on the top surface of the inner chip dielectric pattern 322 may be inner chip upper pads of the inner chip 300. In some embodiments, the inner chip upper pads of the inner chip 300 may be separate pads disposed on the top surface of the inner chip dielectric pattern 322. The inner chip wiring pattern 324 may include a conductive material.

Inner chip connection terminals 326 may be disposed on the inner chip wiring layer 320. The inner chip connection terminals 326 may be coupled to top surfaces of the inner chip upper pads. In some cases, for example, the inner chip connection terminals 326 may be coupled to top surfaces of the inner chip wiring pattern 324. The inner chip connection terminals 326 may include solder bumps or pad patterns.

The inner chip 300 may further include inner chip vias 330 that vertically penetrate the inner chip base layer 310. The inner chip vias 330 may penetrate the inner chip base layer 310 and connect to the inner chip wiring layer 320. The inner chip vias 330 may include a metallic material such as copper (Cu) or tungsten (W).

An inner chip protection layer 340 may be disposed on a bottom surface of the inner chip base layer 310. For example, the inner chip protection layer 340 may be disposed between the bottom surface of the inner chip base layer 310 and the lower redistribution layer 100. The inner chip protection layer 340 may include a dielectric polymer or a photo-imageable dielectric (PID).

Inner chip lower pads 350 may be disposed in the inner chip base layer 310. The inner chip lower pads 350 may be exposed on a bottom surface of the inner chip protection layer 340. The inner chip vias 330 may be coupled to top surfaces of the inner chip lower pads 350. In some cases, for example, the inner chip lower pads 350 may be connected to the inner chip dielectric pattern 322 through the inner chip vias 330.

The inner chip 300 may be mounted on the lower redistribution layer 100. For example, the inner chip 300 may be flip-chip mounted on the lower redistribution layer 100. For example, second inner connection terminals 352 may be disposed on the inner chip lower pads 350 of the inner chip 300. For example, the second inner connection terminals 352 may be disposed between the inner chip lower pads 350 of the inner chip 300 and the substrate wiring patterns 140 of the lower redistribution layer 100. The second inner connection terminals 352 may connect the inner chip lower pads 350 to the substrate wiring patterns 140 of the lower redistribution layer 100. In some cases, the second inner connection terminals 352 may include solder balls.

Conductive posts 410 may be disposed on the lower redistribution layer 100. The conductive posts 410 may be horizontally spaced apart from the bridge chip 200 and the inner chip 300. The conductive posts 410 may be disposed on an edge of the lower redistribution layer 100. The conductive posts 410 may be disposed on the substrate wiring patterns 140 of the lower redistribution layer 100. Each of the conductive posts 410 may be coupled to a top surface of one of the substrate wiring patterns 140. The conductive posts 410 may connect the lower redistribution layer 100 to an upper redistribution layer 430. For example, the conductive posts 410 may refer to as the vertical connection terminals. The conductive posts 410 may be shaped like a column that extends vertically. For example, the conductive posts 410 may have a pillar shape. The via part 144 of the substrate wiring patterns 140 of the lower redistribution layer 100 may be disposed below the conductive posts 410. Thus, the via parts 144 may support the conductive posts 410 and the pad parts 142 of the substrate wiring patterns 140 that support the conductive posts 410. Accordingly, the semiconductor package may have an increased structural stability. The conductive posts 410 may include a conductive material. The conductive posts 410 may include a metallic material such as copper (Cu) or tungsten (W).

A first molding layer 420 may be disposed on the lower redistribution layer 100. On the lower redistribution layer 100, the first molding layer 420 may surround the bridge chip 200, the inner chip 300, and the conductive posts 410. The first molding layer 420 may cover the bridge wiring layer 220 of the bridge chip 200 and the inner chip wiring layer 320 of the inner chip 300. The first molding layer 420 may surround the bridge connection terminals 226 of the bridge chip 200 and the inner chip connection terminals 326 of the inner chip 300. In some cases, a top surface of the bridge connection terminals 226 and a top surface of the inner chip connection terminals 326 might not be covered by the first molding layer 420. In some cases, a top surface of the first molding layer 420 may be coplanar with the top surface of the bridge connection terminals 226 and the top surface of the inner chip connection terminals 326.

The conductive posts 410 may vertically penetrate the first molding layer 420 and coupled to the substrate wiring patterns 140. In some cases, the top surface of the conductive posts 410 might not be covered by the first molding layer 420. In some cases, the top surface of the first molding layer 420 may be coplanar with the top surface of the conductive posts 410. In some cases, each of the top surfaces of the first molding layer 420, the bridge connection terminals 226, the inner chip connection terminals 326, and the conductive posts 410 may be substantially coplanar with each other. In some cases, the first molding layer 420 may cover a portion of the top surface and side surfaces of the substrate wiring patterns 140. In some cases, the first molding layer 420 may cover the top surface of the substrate dielectric pattern 130. The first molding layer 420 may include a dielectric material. For example, the first molding layer 420 may include a dielectric polymer material such as an epoxy molding compound (EMC). In some embodiments, the first molding layer 420 may include a dielectric material such as silicon oxide (SiO), silicon nitride (SiN), or silicon oxynitride (SiON).

An upper redistribution layer 430 may be disposed on the first molding layer 420. The upper redistribution layer 430 may cover the top surface of the first molding layer 420. In some cases, the upper redistribution layer 430 may cover the top surfaces of the first molding layer 420, the bridge connection terminals 226, the inner chip connection terminals 326, and the conductive posts 410. The upper redistribution layer 430 may include a plurality of wiring layers that are sequentially stacked on the top surface of the first molding layer 420. Each of the wiring layers may include an upper dielectric pattern 432 and an upper wiring pattern 434 disposed on the upper dielectric pattern 432. For example, the upper redistribution layer 430 may include a plurality of stacked upper dielectric patterns 432 and upper wiring patterns 434 disposed between or within the upper dielectric patterns 432. In one wiring layer, the upper wiring pattern 434 may include a head part that horizontally extends on a top surface of the upper dielectric pattern 432 and a via part that extends into the upper dielectric pattern 432 from a bottom surface of the head part. For example, the via part of the upper wiring pattern 434 may be substantially coplanar with the upper dielectric pattern 432. The via part of the upper wiring pattern 434 may penetrate the upper dielectric pattern 432 and coupled to the head part of the upper wiring pattern 434 of an another wiring layer. For example, the head part may be a horizontal wiring in the upper redistribution layer 430, and the via part may be a vertical wiring in the upper redistribution layer 430.

The upper wiring pattern 434 of a lowermost one of the wiring layers may be connected to the bridge connection terminals 226 of the bridge chip 200, the inner chip connection terminals 326 of the inner chip 300, and the conductive posts 410. For example, the upper redistribution layer 430 may be in contact with the top surface of the first molding layer 420. In some cases, the via part of the upper wiring pattern 434 of the lowermost wiring layer may be coupled to the bridge connection terminals 226, the inner chip connection terminals 326, and the conductive posts 410 that are exposed on the top surface of the first molding layer 420. For example, the bottom surface of the via part of the upper wiring pattern 434 of the lowermost wiring layer may be in direct contact with the top surfaces of the bridge connection terminals 226, the inner chip connection terminals 326, and the conductive posts 410.

The upper wiring pattern 434 of an uppermost one of the wiring layers may be pads for mounting another semiconductor device, semiconductor chip, or semiconductor apparatus onto the upper redistribution layer 430. The head part of the upper wiring pattern 434 of the uppermost wiring layer may be disposed on a top surface of the upper dielectric pattern 432. As a result, the head part of the upper wiring pattern 434 of the uppermost wiring layer may be disposed on a top surface of the upper redistribution layer 430. For example, the head part of the upper wiring pattern 434 of the uppermost wiring layer may be exposed without being covered by the upper dielectric pattern 432. The head part of the upper wiring pattern 434 of the uppermost wiring layer may be upper substrate pads of the upper redistribution layer 430.

The upper dielectric pattern 432 may include prepreg, Ajinomoto build-up film (ABF), flame retardant 4 (FR-4), or bismaleimide triazine (BT). The upper wiring patterns 434 may include copper (Cu), aluminum (Al), silver (Ag), tin (Sn), gold (Au), nickel (Ni), lead (Pb), titanium (Ti), or any combination thereof.

According to some embodiments of the present inventive concepts, a package substrate includes the lower redistribution layer 100, the bridge chip 200, the inner chip 300, the conductive posts 410, the first molding layer 420, and the upper redistribution layer 430. In some embodiments, a first apparatus may be disposed on the upper redistribution layer 430. For example, the first apparatus may be the first semiconductor chip 500. The first semiconductor chip 500 may include a first chip base layer 510 and a first chip wiring layer 520.

The first chip base layer 510 may include a semiconductor substrate. For example, the first chip base layer 510 may be a semiconductor substrate such as a semiconductor wafer. A first integrated circuit may be disposed on a bottom surface of the first chip base layer 510. The first integrated circuit may include a logic circuit or a memory circuit. For example, the first semiconductor chip 500 may be a logic chip or a memory chip. The present inventive concepts, however, are not necessarily limited thereto. For example, the first semiconductor chip 500 may include a logic chip, a memory chip, a passive element, or a semiconductor chip including various integrated elements. In some cases, a bottom surface of the first semiconductor chip 500 may be an active surface, and a top surface of the first semiconductor chip 500 may be an inactive surface. For example, the first semiconductor chip 500 may be disposed in a face-down state on the upper redistribution layer 430.

The first chip wiring layer 520 may be disposed on the bottom surface of the first chip base layer 510. For example, the first chip wiring layer 520 may be disposed between the bottom surface of the first chip base layer 510 and the upper redistribution layer 430. For example, the first chip wiring layer 520 may include a first chip dielectric pattern 522 and a first chip wiring pattern 524 formed on the bottom surface of the first chip base layer 510. In some embodiments, the first chip wiring layer 520 may include a circuit pattern or a protection layer.

On the bottom surface of the first chip base layer 510, the first chip dielectric pattern 522 may cover the first integrated circuit. In some cases, the first integrated circuit may be disposed between the first chip base layer 510 and the first chip dielectric pattern 522. The first chip dielectric pattern 522 may include a dielectric material.

The first chip wiring pattern 524 may be disposed in the first chip dielectric pattern 522. In some cases, the first chip wiring pattern 524 may be electrically connected to the first integrated circuit formed on the bottom surface of the first chip base layer 510. The first chip wiring pattern 524 may include a conductive material.

FIG. 8 depicts one layer of the first chip dielectric pattern 522, but the present inventive concepts are not necessarily limited thereto. The first chip dielectric pattern 522 may include a plurality of dielectric layers, and the first chip wiring pattern 524 may be a wiring pattern disposed in the plurality of dielectric layers.

The first semiconductor chip 500 may include first chip pads disposed on the bottom surface of the first semiconductor chip 500. The first chip pads may be a portion of the first chip wiring pattern 524 exposed on a bottom surface of the first chip dielectric pattern 522. In some cases, the first chip pads may be separate pads disposed on the bottom surface of the first chip dielectric pattern 522 and the first chip pads are connected to the first chip wiring pattern 524. The first chip pads may be electrically connected through the first chip wiring pattern 524 to the first integrated circuit.

The first semiconductor chip 500 may be mounted on the upper redistribution layer 430. For example, the first semiconductor chip 500 may be flip-chip mounted on the upper redistribution layer 430. The first semiconductor chip 500 may be electrically connected through first connection terminals 530 to the upper redistribution layer 430. The first connection terminals 530 may be disposed between the first chip pads of the first semiconductor chip 500 and the upper substrate pads of the upper redistribution layer 430. In some cases, the first connection terminals 530 may be disposed between the first chip wiring pattern 524 of the first semiconductor chip 500 and the upper wiring pattern 434 of the upper redistribution layer 430. The first semiconductor chip 500 may be electrically connected to the bridge chip 200 through the first chip pads, the first connection terminals 530, the upper redistribution layer 430, and the bridge connection terminals 226. In some cases, the first semiconductor chip 500 may be electrically connected to the lower redistribution layer 100 through the first chip pads, the first connection terminals 530, the upper redistribution layer 430, and the conductive posts 410. The first semiconductor chip 500 may be electrically connected to the inner chip 300 through the first chip pads, the first connection terminals 530, the upper redistribution layer 430, and the inner chip connection terminals 326.

In some embodiments, a second apparatus may be disposed on the upper redistribution layer 430. For example, the second apparatus may be the second semiconductor chip 600. The second semiconductor chip 600 may be horizontally spaced apart from the first semiconductor chip 500. The second semiconductor chip 600 may include a second chip base layer 610 and a second chip wiring layer 620.

The second chip base layer 610 may include a semiconductor substrate. For example, the second chip base layer 610 may be a semiconductor substrate such as a semiconductor wafer. A second integrated circuit may be disposed on a bottom surface of the second chip base layer 610. The second integrated circuit may include a logic circuit or a memory circuit. For example, the second semiconductor chip 600 may be a logic chip or a memory chip. The present inventive concepts, however, are not necessarily limited thereto. For example, the second semiconductor chip 600 may include a logic chip, a memory chip, a passive element, or a semiconductor chip including various integrated elements. In some cases, the second semiconductor chip 600 may be the same as the first semiconductor chip 500. In some cases, the second semiconductor chip 600 may be different from the first semiconductor chip 500. A bottom surface of the second semiconductor chip 600 may be an active surface, and a top surface of the second semiconductor chip 600 may be an inactive surface. For example, the second semiconductor chip 600 may be disposed in a face-down state on the upper redistribution layer 430.

The second chip wiring layer 620 may be disposed on the bottom surface of the second chip base layer 610. For example, the second chip wiring layer 620 may include a second chip dielectric pattern 622 and a second chip wiring pattern 624 disposed on the bottom surface of the second chip base layer 610. In some embodiments, the second chip wiring layer 620 may include a circuit pattern or a protection layer.

On the bottom surface of the second chip base layer 610, the second chip dielectric pattern 622 may cover the second integrated circuit. In some cases, the second integrated circuit may be disposed between the second chip base layer 610 and the second chip dielectric pattern 622. The second chip dielectric pattern 622 may include a dielectric material.

The second chip wiring pattern 624 may be disposed in the second chip dielectric pattern 622. The second chip wiring pattern 624 may be electrically connected to the second integrated circuit formed on the bottom surface of the second chip base layer 610. The second chip wiring pattern 624 may include a conductive material.

FIG. 8 depicts one layer of the second chip dielectric pattern 622, but the present inventive concepts are not necessarily limited thereto. For example, the second chip dielectric pattern 622 may include a plurality of dielectric layers, and the second chip wiring pattern 624 may be a wiring pattern disposed in the plurality of dielectric layers.

The second semiconductor chip 600 may have second chip pads disposed on the bottom surface of the second semiconductor chip 600. The second chip pads may be a portion of the second chip wiring pattern 624 exposed on a bottom surface of the second chip dielectric pattern 622. In some cases, the second chip pads may be separate pads that are disposed on the bottom surface of the second chip dielectric pattern 622 and the second chip pads are connected to the second chip wiring pattern 624. The second chip pads may be electrically connected to the second integrated circuit through the second chip wiring pattern 624.

The second semiconductor chip 600 may be mounted on the upper redistribution layer 430. For example, the second semiconductor chip 600 may be flip-chip mounted on the upper redistribution layer 430. The second semiconductor chip 600 may be electrically connected to the upper redistribution layer 430 through second connection terminals 630. The second connection terminals 630 may be disposed between the second chip pads of the second semiconductor chip 600 and the upper substrate pads of the upper redistribution layer 430. In some cases, the second connection terminals 630 may be disposed between the second chip wiring pattern 624 of the second semiconductor chip 600 and the upper wiring pattern 434 of the upper redistribution layer 430. The second semiconductor chip 600 may be electrically connected to the bridge chip 200 through the second chip pads, the second connection terminals 630, the upper redistribution layer 430, and the bridge connection terminals 226. In some cases, the second semiconductor chip 600 may be electrically connected to the lower redistribution layer 100 through the second chip pads, the second connection terminals 630, the upper redistribution layer 430, and the conductive posts 410. The second semiconductor chip 600 may be electrically connected to the inner chip 300 through the second chip pads, the second connection terminals 630, the upper redistribution layer 430, and the inner chip connection terminals 326.

In some cases, the bridge chip 200 may electrically connect the first semiconductor chip 500 and the second semiconductor chip 600 to each other. For example, the first semiconductor chip 500 may be connected to the second semiconductor chip 600 through the first chip pads, the first connection terminals 530, the upper redistribution layer 430, the bridge connection terminals 226, the bridge chip 200, the second connection terminals 630, and the second chip pads.

A second molding layer 440 may be disposed on the upper redistribution layer 430. On the upper redistribution layer 430, the second molding layer 440 may surround the first semiconductor chip 500 and the second semiconductor chip 600. The second molding layer 440 may expose the top surface of the first semiconductor chip 500 and the top surface of the second semiconductor chip 600. In some embodiments, the first semiconductor chip 500 and the second semiconductor chip 600 may be covered by the second molding layer 440. The second molding layer 440 may fill a space between the first semiconductor chip 500 and the upper redistribution layer 430 and a space between the second semiconductor chip 600 and the upper redistribution layer 430. In some cases, a top surface of the second molding layer 440 may be substantially coplanar with the top surfaces of the first semiconductor chip 500 and the second semiconductor chip 600. The second molding layer 440 may surround the first connection terminals 530 below the first semiconductor chip 500 and the second connection terminals 630 below the second semiconductor chip 600. In some cases, the second molding layer 440 may cover the upper surface of the upper redistribution layer 430. The second molding layer 440 may include a dielectric material. For example, the second molding layer 440 may include a dielectric polymer material such as an epoxy molding compound (EMC).

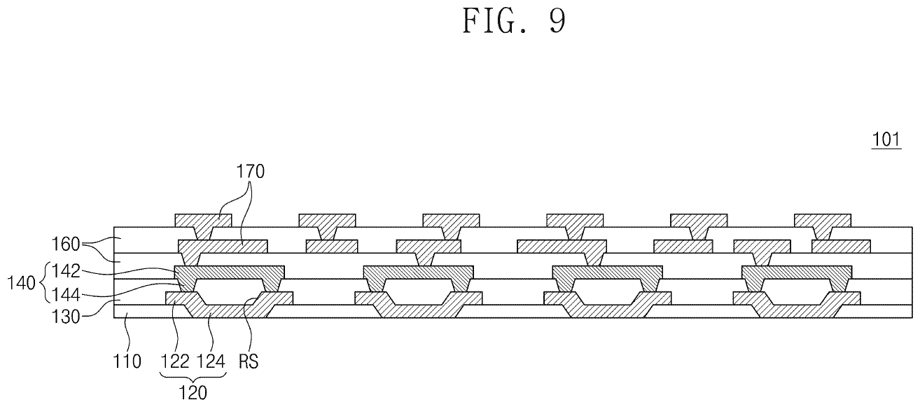

FIG. 9 illustrates a cross-sectional view of a wiring substrate according to some embodiments of the present inventive concepts. As described in FIG. 1, the substrate wiring patterns 140 of the wiring substrate 100 are pad layers for mounting a semiconductor chip, a semiconductor device, or a semiconductor apparatus on the wiring substrate 100, but the present inventive concepts are not necessarily limited thereto.

Referring to FIG. 9, a wiring substrate 101 may be a redistribution substrate. For example, the wiring substrate 101 may include at least two substrate wiring layers, a substrate protection layer 110, and under-bump pads 120.

The substrate protection layer 110 and the under-bump pads 120 may be substantially the same as or similar to the substrate protection layer 110 and the under-bump pads 120 described with reference to FIGS. 1 and 2. For example, the substrate protection layer 110 may cover a bottom surface of a lowermost one of the substrate wiring layers. The under-bump pads 120 may include an upper part 122 disposed on a top surface of the substrate protection layer 110. In some cases, the under-bump pads 120 may include a lower part 124 that penetrates the substrate protection layer 110 and is exposed on a bottom surface of the substrate protection layer 110. Each of the under-bump pads 120 may have a recess RS formed on a top surface thereof.

In some cases, a first substrate wiring layer may refer to the lowermost substrate wiring layer connected to the under-bump pads 120. In some cases, a second substrate wiring layer may refer to a substrate wiring layer or substrate wiring layers stacked on the first substrate wiring layer.

The first substrate wiring layer may include a first substrate dielectric pattern 130 and first substrate wiring patterns 140 in the first substrate dielectric pattern 130. The first substrate dielectric pattern 130 and the first substrate wiring patterns 140 may be substantially the same as or similar to the substrate dielectric pattern 130 and the substrate wiring patterns 140 described with reference to FIGS. 1 to 7. For example, on the substrate protection layer 110, the first substrate dielectric pattern 130 may cover a portion of the under-bump pads 120. The first substrate wiring patterns 140 may include a pad part 142 disposed on a top surface of the first substrate dielectric pattern 130. In some cases, the first substrate wiring patterns 140 may include a via part 144 that penetrates the first substrate dielectric pattern 130 and is coupled to the top surfaces of the under-bump pads 120. The via part 144 may be horizontally spaced apart from the recess RS of the under-bump pad 120. In some cases, the via part 144 may have a closed or open curve shape that surrounds the recess RS or may have a linear shape spaced apart from the recess RS in the plan view.

One or more second substrate wiring layers may be stacked on the first substrate wiring layer. Each of the second substrate wiring layers may include a second substrate dielectric pattern 160 and second substrate wiring patterns 170 disposed in the second substrate dielectric pattern 160. The second substrate wiring patterns 170 of one second substrate wiring layer may be electrically connected to the second substrate wiring patterns 170 of a neighboring second substrate wiring layer.

For example, the second substrate dielectric pattern 160 may be formed of the same material as the material of the first substrate dielectric pattern 130. The second substrate dielectric pattern 160 may include a dielectric polymer or a photo-imageable dielectric (PID). In some embodiments, the second substrate dielectric pattern 160 may include a dielectric material.

The second substrate wiring patterns 170 may include a pad part that horizontally extends on a top surface of the second substrate dielectric pattern 160. In some cases, the second substrate wiring patterns 170 may include a via part that extends into the second substrate dielectric pattern 160 from a bottom surface of the pad part toward a bottom surface of the second substrate dielectric pattern 160. The via parts of the second substrate wiring patterns 170 may penetrate the second substrate dielectric pattern 160 and coupled to the head parts of the second substrate wiring patterns 170 of another second substrate wiring layers. For example, the head part may be a horizontal wiring in the second substrate wiring layer and the via part may be a vertical wiring in the second substrate wiring layer.

The second substrate wiring patterns 170 of a lowermost one of the second substrate wiring layers may be connected to the first substrate wiring patterns 140 of the first substrate wiring layer. For example, the via parts of the second substrate wiring patterns 170 of the lowermost second substrate wiring layer may penetrate the second substrate dielectric pattern 160 and coupled to the first substrate wiring patterns 140. For example, a bottom surface of the via parts of the second substrate wiring patterns 170 of the lowermost second substrate wiring layer may directly contact the top surface of the first substrate wiring patterns 140.

The second substrate wiring patterns 170 of an uppermost one of the second substrate wiring layers may be pads for mounting other devices on the wiring substrate 101. For example, the pad parts of the second substrate wiring patterns 170 of the uppermost second substrate wiring layer may be disposed on the top surface of the second substrate dielectric pattern 160. In some cases, the pad parts of the second substrate wiring patterns 170 of the uppermost second substrate wiring layer may be disposed on a top surface of the uppermost second substrate wiring layer. The pad parts of the second substrate wiring patterns 170 of the uppermost second substrate wiring layer may be exposed without being covered by the second substrate dielectric pattern 160.

The second substrate wiring patterns 170 may be formed of the same material as the material of the first substrate wiring patterns 140. In some cases, the second substrate wiring patterns 170 may include metal such as copper (Cu).

In some embodiments, the second substrate wiring pattern 170 may include a seed layer. For example, the seed layer may be interposed between the second substrate wiring pattern 170 and the second substrate dielectric pattern 160. The seed layer may extend between the second substrate wiring pattern 170 and the first substrate wiring pattern 140. In some cases, the seed layer may be interposed between the second substrate wiring pattern 170 and another second substrate wiring pattern 170. The seed layer may include a metallic material such as gold (Au).

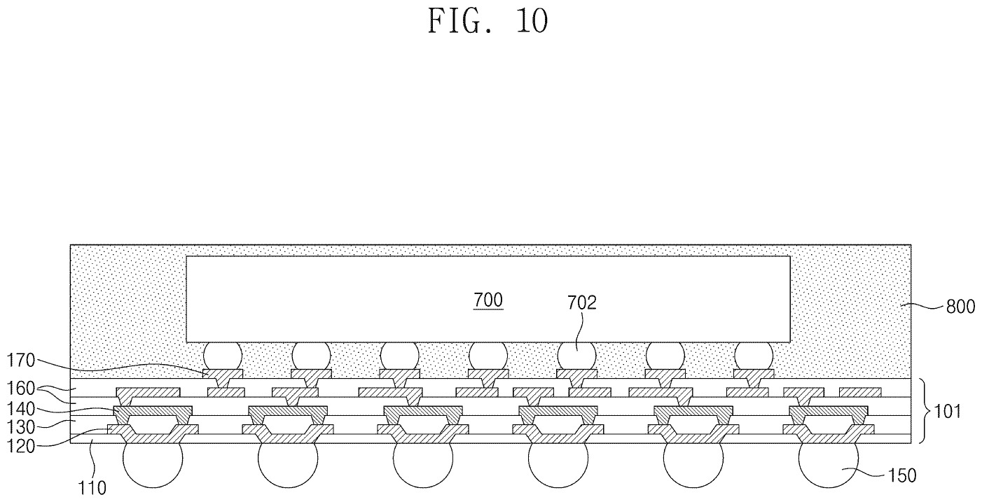

FIG. 10 illustrates a cross-sectional view of a semiconductor package according to some embodiments of the present inventive concepts. Referring to FIG. 10, a wiring substrate 101 may be provided. The wiring substrate 101 may be an example of, or includes aspects of, the wiring substrate 101 described with reference to FIG. 9. In some cases, external terminals 150 may be disposed on bottom surfaces of the under-bump pads 120 exposed on the bottom surface of the substrate protection layer 110. In some cases, external terminals 150 may include a solder ball or solder bumps.

In some embodiments, a semiconductor chip 700 may be disposed on the wiring substrate 101. The semiconductor chip 700 may be a logic chip or a memory chip. The present inventive concepts, however, are not necessarily limited thereto. For example, the semiconductor chip 700 may include a logic chip, a memory chip, a passive element, or a semiconductor chip including various integrated elements. In some cases, a bottom surface of the semiconductor chip 700 may be an active surface and a top surface of the semiconductor chip 700 may be an inactive surface. For example, the active surface of the semiconductor chip 700 may be adjacent to the wiring substrate 101. For example, the semiconductor chip 700 may be disposed in a face-down state on the wiring substrate 101.

The semiconductor chip 700 may be mounted on the wiring substrate 101. For example, the semiconductor chip 700 may be flip-chip mounted on the wiring substrate 101. The semiconductor chip 700 may be electrically connected to the wiring substrate 101 through connection terminals 702. The connection terminals 702 may be disposed between chip pads of the semiconductor chip 700 and the second substrate wiring patterns 170 of an uppermost second substrate wiring layer of the wiring substrate 101. In some cases, the semiconductor chip 700 depicted in FIG. 10 is flip-chip mounted on the wiring substrate 101, but the present inventive concepts are not necessarily limited thereto. In some cases, the semiconductor chip 700 may be wire-bonded mounted on the wiring substrate 101.

A molding layer 800 may be disposed on the wiring substrate 101. For example, the molding layer 800 may cover the wiring substrate 101 and the semiconductor chip 700. The molding layer 800 may include a dielectric material. For example, the first molding layer 420 may include a dielectric polymer material such as an epoxy molding compound (EMC).

FIGS. 11 to 15 illustrate a method for forming a wiring substrate according to some embodiments of the present inventive concepts. Referring to FIG. 11, a carrier substrate 900 may be provided. The carrier substrate 900 may be a dielectric substrate including glass or polymer. In some cases, the carrier substrate 900 may be a conductive substrate including metal. In some embodiments, an adhesive member may be disposed on a top surface of the carrier substrate 900. For example, the adhesive member may include a glue tape. A substrate protection layer 110 may be disposed on the carrier substrate 900. The substrate protection layer 110 may be formed by a deposition process or a coating process. In some cases, the substrate protection layer 110 may be disposed on the adhesive member.

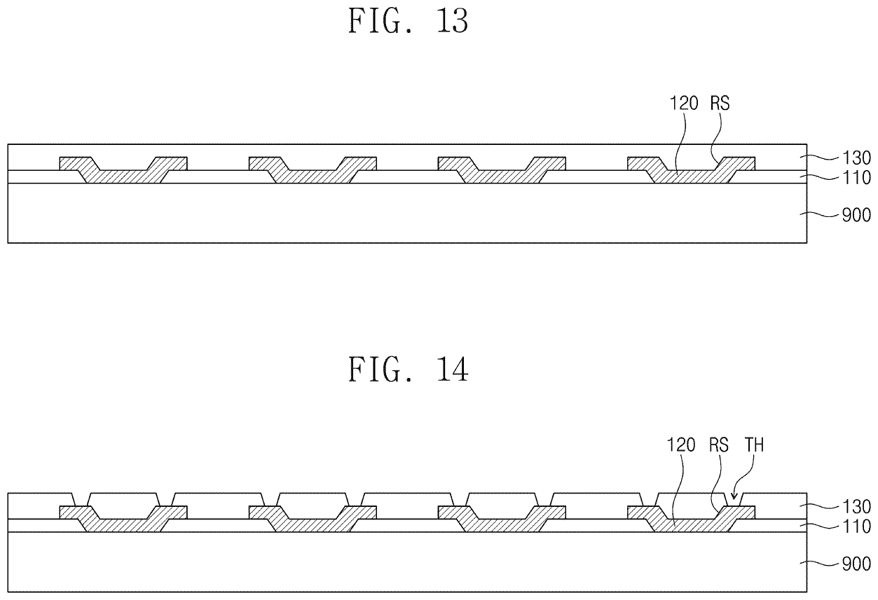

Referring to FIG. 12, the substrate protection layer 110 may be patterned to form openings for forming under-bump pads (see 120 of FIG. 13). For example, portions of the under-bump pads 120 are removed to form the openings. The under-bump pads 120 may be pads to which are coupled external terminals such as solder balls, and may be formed to have large widths. Therefore, the openings may also be formed to have large widths.

A first conductive layer 125 may be formed on the substrate protection layer 110. For example, a seed layer may be formed to conformally cover a top surface of the substrate protection layer 110 and to also conformally cover bottom and inner lateral surfaces of the openings. Then, the seed layer may be used as a seed to perform a plating process to form the first conductive layer 125 on the substrate protection layer 110 and the openings. For example, during the plating process, a thin layer of metal is deposited onto the substrate protection layer 110. In some cases, the plating process may include electroplating, electroless plating (or autocatalytic plating), an immersion plating, a physical vapor deposition (PVD) process, or evaporation.

As the openings are formed to have large widths, shapes of the openings may be transferred onto the first conductive layer 125 formed on the openings. For example, on the openings, recesses RS may be formed on a top surface of the first conductive layer 125. For example, the first conductive layer 125 may be formed to conformally cover the top surface of the substrate protection layer 110 and the bottom and inner lateral surfaces of the openings. In some cases, the first conductive layer 125 has a uniform thickness.

In some cases, the first conductive layer 125 is formed from a conductive material which is grown from the top surface of the substrate protection layer 110 and the bottom and inner lateral surfaces of the openings. For example, when the conductive material is grown, the conductive material might not completely fill the wide regions (or recesses on the conductive material onto which the openings are transferred) in the openings. In some cases, the width of the recesses RS measured in the horizontal direction is less than the width of the openings of the substrate protection layer 110. In some cases, the horizontal direction is parallel a top surface of the carrier substrate 900.

Referring to FIG. 13, the first conductive layer 125 may be patterned to form under-bump pads 120. For example, portions of the first conductive layer 125 are removed to form the under-bump pads 120. The under-bump pads 120 may have recesses RS formed on top surfaces of the under-bump pads 120.

A substrate dielectric pattern 130 may be formed on the substrate protection layer 110. The substrate dielectric pattern 130 may be formed by a deposition process or a coating process. On the substrate protection layer 110, the substrate dielectric pattern 130 may cover the under-bump pads 120. In some cases, the substrate dielectric pattern 130 may cover the substrate protection layer 110, the under-bump pads 120, and the recesses RS of the under-bump pads 120.

Referring to FIG. 14, the substrate dielectric pattern 130 may be patterned to form through holes TH for forming the under-bump pads 120. In some cases, portions of the substrate dielectric pattern 130 are removed to form the through hole TH. The through holes TH may represent regions in which via parts of substrate wiring patterns are formed in a subsequent process. The through holes TH may expose the top surfaces of the under-bump pads 120. The through holes TH may have tapered shapes. In some cases, each of the through holes has a width that decreases with decreasing distance toward the under-bump pad 120. For example, a width of the through hole TH coplanar with the top surface of the substrate dielectric pattern 130 is greater than a width of the through hole TH coplanar with the top surface of the upper part of the under-bump pad 120. The widths of the through holes TH may be less than the widths of the openings formed in the substrate protection layer 110 for forming the under-bump pads 120. The through holes TH may be spaced apart from the recesses RS of the under-bump pads 120. For example, a pair of through holes TH may be formed at the two ends of an under-bump pad 120. The through holes TH may have a closed or open curve shape that surrounds the recess RS. In some cases, the through holes may have a linear shape spaced apart from the recess RS.

According to some embodiments of the present inventive concepts, the through holes TH may be formed to have tapered shapes, where each of the through holes TH has a width that decreases with decreasing distance toward the under-bump pad 120. For example, the through holes TH might not be formed on bottom surfaces of the recesses RS of the under-bump pads 120, but may be formed on the top surfaces of the under-bump pads 120, and thus the through holes TH may have small depths. In some cases, a small difference in width between top and bottom ends of the through holes TH may occur. Accordingly, a via part 144 of the substrate wiring pattern 140 formed in the through hole TH may have a small resistance. In some cases, the via part 144 and the under-bump pad 120 may have a small contact resistance therebetween. In some cases, a wiring substrate 100 may be formed to have improved electrical properties.

In some embodiments, when the through holes TH are formed on the bottom surfaces of the recesses RS of the under-bump pads 120, the through holes TH may have increased depths and may be formed to have small widths at the bottom ends thereof. As a result, a large difference in width between the top and bottom ends of the through holes TH may occur, and a large contact resistance may exist between the via part (see 144 of FIG. 2) and the under-bump pad 120.

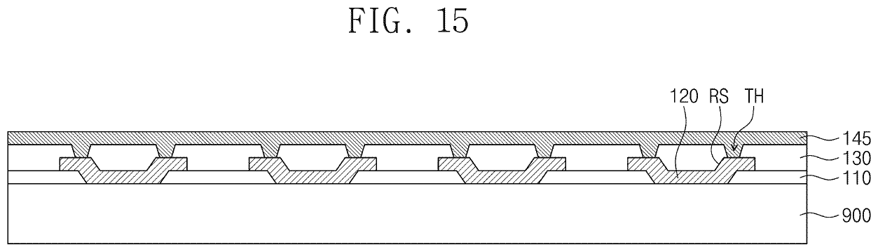

Referring to FIG. 15, a second conductive layer 145 may be formed on the substrate dielectric pattern 130. For example, a seed layer may be formed to conformally cover a top surface of the substrate dielectric pattern 130 and conformally cover a bottom surface and inner lateral surfaces of the through holes TH. Then, the seed layer may be used as a seed to perform a plating process to form the second conductive layer 145 on the substrate dielectric pattern 130 and the through holes TH.

The through holes TH may have widths relatively less than the widths of the openings formed in the substrate protection layer 110 for forming the under-bump pads 120. During the plating process, a conductive material may be grown from the top surface of the substrate dielectric pattern 130 and the bottom surface and inner lateral surfaces of the through holes TH. For example, the conductive material may fill the space or regions in the through holes TH. Therefore, the second conductive layer 145 may have a flat top surface after the plating process.

Referring back to FIG. 1, the second conductive layer 145 may be patterned to form substrate wiring patterns 140. For example, portions of the second conductive layer 145 may be removed to form the substrate wiring patterns 140. Then, the carrier substrate 900 may be removed. The removal of the carrier substrate 900 may expose the bottom surface of the substrate protection layer 110 and the bottom surface of the under-bump pads 120 of the wiring substrate 100. In some cases, external terminals may be disposed on the exposed bottom surfaces of the under-bump pads 120.

In a wiring substrate and a semiconductor package including the same in accordance with some embodiments of the present inventive concepts, a substrate wiring pattern may have a small difference in width between upper portion and lower portion of the substrate wiring pattern. For example, the lower portion of the via part might not be excessively small. Thus, the via part may have a small electrical resistance, the via part and an under-bump pad may have a small contact resistance therebetween, and the wiring substrate and the semiconductor package may have improved electrical properties. In addition, as the lower portion of the via part is not excessively small, the via part might not be damaged by external impact. Accordingly, the wiring substrate and the semiconductor package may have improved structural stability.

Although the present inventive concepts have been described in connection with some embodiments of the present inventive concepts illustrated in the accompanying drawings, it will be understood by one of ordinary skill in the art that variations in form and detail may be made therein without departing from the spirit and essential feature of the present inventive concepts. The above disclosed embodiments should thus be considered illustrative and not restrictive.

What is claimed is:

1. A wiring substrate, comprising:
a protection layer;
an under-bump pad including an upper part disposed on a top surface of the protection layer and a lower part penetrating the protection layer, wherein the lower part of the under-bump pad is exposed on a bottom surface of the protection layer, and the under-bump pad includes a recess region directed into a bottom surface of the under-bump pad from a top surface of the under-bump pad;
a dielectric pattern disposed on the protection layer, wherein the dielectric pattern covers a portion of the under-bump pad and fills the recess region; and
a conductive pattern disposed on the dielectric pattern,
wherein the conductive pattern includes:
a pad part disposed on a top surface of the dielectric pattern; and
a via part that vertically penetrates the dielectric pattern and is coupled to the top surface of the under-bump pad,
wherein a width of the upper part of the under-bump pad is greater than a width of the pad part of the conductive pattern, and
wherein the via part of the conductive pattern is spaced apart from the recess region.

2. The wiring substrate of claim 1, wherein the via part of the conductive pattern has an annular shape, a ring shape, or a closed curve shape that surround the recess region in a plan view.

3. The wiring substrate of claim 1, wherein the via part of the conductive pattern has an open curve shape which surrounds the recess region and a region of the via part of the conductive pattern is opened in a plan view.

4. The wiring substrate of claim 1, wherein a first width of a bottom end of the via part of the conductive pattern is less than a second width of a top end of the via part of the conductive pattern.

5. The wiring substrate of claim 4, wherein the first width is about 0.9 times to about 1 time the second width.

6. The wiring substrate of claim 1, wherein a width of the via part of the conductive pattern ranges from about 5 micrometers to about 15 micrometers.

7. The wiring substrate of claim 1, wherein a depth of the recess region of the under-bump pad ranges from about 3 micrometers to about 5 micrometers.

8. The wiring substrate of claim 1, wherein a height of the via part of the conductive pattern ranges from about 5 micrometers to about 20 micrometers.

9. A semiconductor package, comprising:
a package substrate;
a first apparatus disposed on the package substrate; and
a second apparatus disposed on the package substrate and horizontally spaced apart from the first apparatus,
wherein the package substrate includes:
a lower redistribution layer;
a bridge chip disposed on the lower redistribution layer;
an upper redistribution layer disposed on the bridge chip; and
a vertical connection terminal disposed between and connected to the lower redistribution layer and the upper redistribution layer,
wherein the lower redistribution layer includes:
a protection layer;
an under-bump pad disposed on a top surface of the protection layer and penetrating the protection layer, wherein the under-bump pad is exposed on a bottom surface of the protection layer;
a dielectric pattern disposed on the protection layer and covering the under-bump pad; and
a conductive pattern disposed on the dielectric pattern,
wherein the conductive pattern includes:
a pad part disposed on a top surface of the dielectric pattern; and
a via part that vertically penetrates the dielectric pattern and is coupled to the under-bump pad,
wherein the bridge chip and the vertical connection terminal are connected to a top surface of the pad part of the conductive pattern, and
wherein the via part of the conductive pattern has an annular shape, a ring shape, or a closed curve shape in a plan view.

10. The semiconductor package of claim 9, wherein:
the under-bump pad includes a recess region directed into a bottom surface the under-bump pad from a top surface of the under-bump pad, and
the via part of the conductive pattern is spaced apart from the recess region.

11. The semiconductor package of claim 10, wherein the via part of the conductive pattern surrounds the recess region in the plan view.

12. The semiconductor package of claim 10, wherein a depth of the recess region of the under-bump pad ranges from about 3 micrometers to about 5 micrometers.

13. The semiconductor package of claim 9, wherein a width of the under-bump pad is greater than a width of the pad part of the conductive pattern.

14. The semiconductor package of claim 9, wherein a first width of a bottom end of the via part of the conductive pattern is less than a second width of a top end of the via part of the conductive pattern.

15. The semiconductor package of claim 14, wherein the first width is about 0.9 times to about 1 time the second width.

16. The semiconductor package of claim 9, further comprising:
a molding layer disposed on the lower redistribution layer and covering the bridge chip,
wherein the vertical connection terminal includes a conductive post on one side of the bridge chip, and the conductive post vertically penetrates the molding layer and connects the lower redistribution layer and the upper redistribution layer.

17. The semiconductor package of claim 16, wherein the via part of the conductive pattern is disposed below the conductive post.

18. A wiring substrate, comprising:
a protection layer;
an under-bump pad disposed on a top surface of the protection layer, wherein the under-bump pad includes a recess region directed into a bottom surface of the under-bump pad from a top surface of the under-bump pad;
a dielectric pattern disposed on the protection layer, wherein the dielectric pattern covers a portion the under-bump pad and fills the recess region; and
a conductive pattern disposed on the dielectric pattern,
wherein the conductive pattern includes:
a pad part disposed on a top surface of the dielectric pattern; and
a via part that vertically penetrates the dielectric pattern and is coupled to the top surface of the under-bump pad,
wherein the via part of the conductive pattern surrounds the recess region in a plan view,
wherein a first width of a bottom end of the via part of the conductive pattern is less than a second width of a top end of the via part of the conductive pattern, and
wherein the first width is about 0.9 times to about 1 time the second width.

19. The wiring substrate of claim 18, wherein the via part of the conductive pattern is spaced apart from the recess region.

20. The wiring substrate of claim 18, wherein the via part of the conductive pattern has an annular shape, a closed curve shape, a ring shape, an open curve shape having a partial region opened, or a stripe shape having linear patterns spaced apart from each other across the recess region in the plan view.
